(19) United States
(12) Patent Application Publication
(10) Pub. No.: US 2024/0145648 A1
(43) Pub. Date: May 2, 2024

(54) LIGHT EMITTING DIODE DISPLAY DEVICE

(71) Applicant: LG DISPLAY CO., LTD., SEOUL (KR)

(72) Inventors: Yanghwan KIM, Gyeonggi-do (KR); MoonBong SONG, Gyeonggi-do (KR); SeongKyong PARK, Gyeonggi-do (KR); Hoon KANG, Gyeonggi-do (KR)

(73) Assignee: LG DISPLAY CO., LTD., SEOUL (KR)

(21) Appl. No.: 18/384,468

(22) Filed: Oct. 27, 2023

(30) Foreign Application Priority Data
Nov. 1, 2022 (KR) 10-2022-0143921

(51) Int. Cl. H01L 33/58; H01L 25/16; H01L 33/24; H01L 33/60

(52) U.S. Cl. CPC H01L 33/58; H01L 25/167; H01L 33/24; H01L 33/60

(57) ABSTRACT

A light emitting diode display device includes a light emitting diode over a substrate, a plurality of patterns provided over the light emitting diode and configured to have a first refractive index, each of the plurality of patterns including an inclined surface, a first planarization layer provided over the plurality of patterns and configured to have a second refractive index different from the first refractive index.

### CROSS-REFERENCE TO RELATED APPLICATION

This application claims the priority of Korean Patent Application No. 10-2022-0143921 filed on Nov. 1, 2022, which is hereby incorporated by reference in its entirety.

### BACKGROUND

### Field of the Disclosure

The present disclosure relates to a display device, and more particularly, to, for example, a light emitting diode display device.

### Description of the Background

A display device is widely used as a display screen of a laptop computer, a tablet computer, a smart phone, a portable display device, and a portable information device display device in addition to a display screen of a television or a monitor. As examples of the display device, a liquid crystal display device and an organic light emitting display device display an image by the use of thin film transistor serving as a switching element. As the liquid crystal display device has a backlight unit, there is a limitation in design, and luminance and response speed may be reduced. Since the organic light emitting display device includes an organic material, the organic light emitting display device is vulnerable to moisture, whereby reliability and lifespan thereof may be deteriorated or lowered.

Recently, research and development of a light emitting diode display device using a micro light emitting diode has been conducted, and the light emitting diode display device has high quality and high reliability, whereby it is spotlighted as a next generation display device.

The description provided in the background section should not be assumed to be prior art merely because it is mentioned in or associated with the background section. The background section may include information that describes one or more aspects of the subject technology.

### SUMMARY

The present disclosure has been made in view of the above limitations, and provides a light emitting display device that substantially obviates one or more of the issues due to limitations and disadvantages described above.

More specifically, the present disclosure is to provide a light emitting display device capable of improving a front luminance.

The present disclosure is also to provide a light emitting diode display device capable of preventing or reducing the dropping or declination of a front luminance when a transfer tolerance occurs.

To achieve these and other aspects of the present disclosure, as embodied and broadly described herein, a light emitting diode display device includes a light emitting diode on a substrate, a plurality of patterns provided on the light emitting diode and configured to include an inclined surface and a first refractive index, a planarization layer provided on the plurality of low refractive patterns and configured to have a second refractive index different from the first refractive index.

In addition to the effects of the present disclosure as mentioned above, additional aspects and features of the present disclosure will be clearly understood by those skilled in the art from the above description of the present disclosure.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate aspects of the disclosure and together with the description serve to explain various principles of the disclosure. The above and other aspects, features and other effects of the present disclosure will be more clearly understood from the following detailed description taken in conjunction with the accompanying drawings, in which:

FIG. 1 is a plan view schematically illustrating a light emitting diode display device according to one or more exemplary aspects of the present disclosure;

FIG. 2 is a plan view illustrating one example of a unit pixel provided in a display area of the display device according to one or more exemplary aspects of the present disclosure;

FIG. 3 is an example of a cross sectional view taken along line I-I′ of FIG. 2;

FIG. 4 illustrates one example of a luminance distribution by each viewing angle of light emitted from a light emitting diode;

FIG. 5 is a plan view illustrating an effective area in a light emitting area;

FIG. 6 illustrates one example of a shape of a low refractive pattern;

FIGS. 7A to 7F illustrates modified examples of a shape of a low refractive pattern;

FIG. 8 is another example of a cross sectional view taken along line I-I′ of FIG. 2;

FIG. 9 shows a luminance distribution for each viewing angle of a light emitting diode display device according to a reference example in which a low refractive pattern and a high refractive lens are not provided;

FIG. 10 shows a luminance distribution for each viewing angle of a light emitting diode display device according to Aspect 1 provided with a low refractive pattern;

FIG. 11 shows a luminance distribution for each viewing angle of a light emitting diode display device according to Aspect 2 provided with a low refractive pattern and a high refractive lens;

FIG. 12 shows a luminance distribution for each viewing angle of a light emitting diode display device according to Aspect 3 provided with a high refractive lens;

FIG. 13 illustrates an example in which a transfer tolerance occurs in the light emitting diode display device according to the Aspect 3;

FIG. 14 illustrates a luminance distribution for each viewing angle of the light emitting diode display device according to the Aspect 3 in which a transfer tolerance occurs;

FIG. 15 illustrates an example in which a transfer tolerance occurs in the light emitting diode display device according to the Aspect 2; and

FIG. 16 illustrates a luminance distribution for each viewing angle of the light emitting diode display device according to the Aspect 2 in which a transfer tolerance occurs.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Various aspects and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects may be provided so that this disclosure may be sufficiently thorough and complete to assist those skilled in the art to fully understand the scope of the present disclosure.

The shapes, sizes, ratios, angles, numbers, dimensions (e.g., lengths, widths, heights, thicknesses, radius, diameters, areas, etc.) and the like, which are illustrated in the drawings to describe various example aspects of the present disclosure are merely given by way of example. Therefore, the present disclosure is not limited to the illustrations in the drawings. Any implementation described herein as an “example” is not necessarily to be construed as preferred or advantageous over other implementations.

A dimension including size and a thickness of each component illustrated in the drawing are illustrated for convenience of description, and the present disclosure is not limited to the size and the thickness of the component illustrated, but it is to be noted that the relative dimensions including the relative size, location and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have,’ and ‘include’ described in the present specification are used, another part may be added unless the terms, such as “only,” is used. An element described in the singular form is intended to include a plurality of elements, and vice versa, unless the context clearly indicates otherwise.

In construing an element, the element is construed as including an error range or tolerance range although there is no explicit description of such an error or tolerance range.

In describing a position relationship, for example, when the position relationship is described as ‘on˜,’ “over˜,” ‘above˜,’ ‘below˜,’ and ‘next to˜,’ one or more portions may be arranged between two other portions unless ‘just,’ “immediate(ly),” or “direct(ly)” is used.

It will be understood that, although the terms “first,” “second,” “A,” “B,” “(a),” and “(b),” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., may be used. These terms are intended to identify the corresponding elements from the other elements, and basis, order, or number of the corresponding elements are not limited by these terms. The expression that an element is “connected” or “coupled” to another element should be understood that the element may directly be connected or coupled to another element but may directly be connected or coupled to another element unless specially mentioned, or a third element may be interposed between the corresponding elements.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various aspects of the present disclosure may be partially or overall coupled to or combined with each other, and may be variously inter-operated with each other and driven technically as those skilled in the art may sufficiently understand. The example aspects of the present disclosure may be carried out independently from each other, or may be carried out together in co-dependent relationship.

Hereinafter, example aspects of the present disclosure will be described in detail with reference to the accompanying drawings.

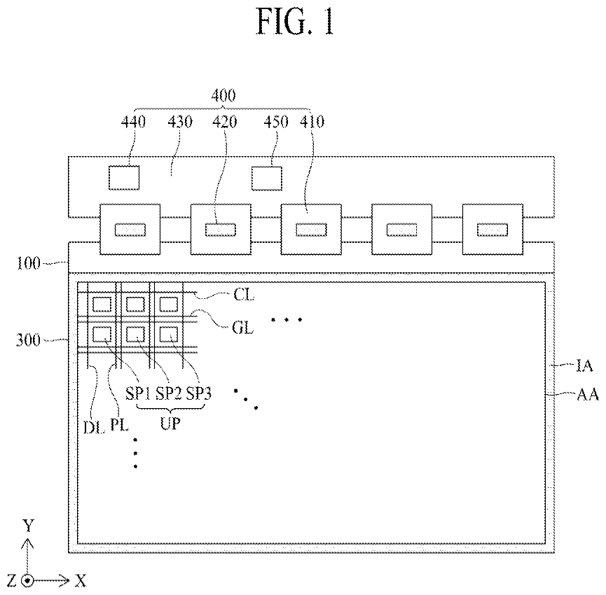

FIG. 1 is a plan view schematically illustrating a light emitting diode display device according to one or more exemplary aspects of the present disclosure.

Hereinafter, for example, X axis indicates a line parallel with a gate line, Y axis indicates a line parallel with a data line, and Z axis indicates a height or thickness direction of a light emitting diode display device.

Referring to FIG. 1, the light emitting diode display device according to one or more exemplary aspects of the present disclosure includes a first substrate 100, a plurality of unit pixels UP, and a second substrate 300. All the components of each display device according to all aspects of the present disclosure are operatively coupled and configured.

The first substrate 100 is a thin film transistor array substrate and may include glass, a plastic material, or a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), or ciclic-olefin copolymer, cyclic olefin copolymer (COC), triacetylcellulose (TAC) film, polyvinyl alcohol (PVA) film, and polystyrene (PS), and the present disclosure is not limited thereto. The first substrate 100 may be divided into a display area AA and a non-display area IA in the vicinity of the display area AA.

The non-display area IA is an area in which an image is not displayed, and the non-display area IA corresponds to an area excluding the display area AA or an area adjacent to the display area AA. The non-display area AA may be an edge area of the first substrate 100 surrounding the display area AA, wherein the non-display area AA may have a relatively narrow width, and may be defined as a bezel area. A wiring (e.g., the data line, the gate line, the power line, or the like) and a circuit (e.g., the data driving circuits, the gate driving circuit, scan driver or the like) for driving the plurality of unit pixels UP in the display area AA may be disposed in the non-display area IA.

The display area AA is an area in which the plurality of unit pixels UP are provided to display an image, and the display area AA corresponds to the remaining area except for the edge area of the first substrate 100.

The plurality of unit pixels UP are provided in the display area AA. The plurality of unit pixels UP may be arranged in such a way that each of the plurality of unit pixels UP has a first reference pixel distance preset along a first direction (e.g., X-axis direction) and has a second reference pixel distance preset along a second direction (e.g., Y-axis direction) in the display area AA. For example, the first reference pixel distance may be defined as a distance between the centers of two adjacent unit pixels UP along the first direction (e.g., X-axis direction), and the second reference pixel distance may be defined as a distance between the centers of two adjacent unit pixels along the second direction (e.g., Y-axis direction). It should be appreciated that the terms “first reference pixel distance” and “the second reference pixel distance” are used as examples herein for convenience of explanation and illustration, and are interchangeable, as should be understood by one of ordinary skill in the art.

Each of the plurality of unit pixels UP may include a plurality of subpixels SP1, SP2, and SP3. For example, each of the plurality of unit pixels UP may include a red subpixel SP1 configured to emit red light, a green subpixel SP2 configured to emit green light, and a blue subpixel SP3 configured to emit blue light. In another example, each of the plurality of unit pixels UP may further include a white subpixel configured to emit white light. However, aspects of the present disclosure are not limited thereto. In some cases, the red, green and blue subpixels may be replaced by a cyan subpixel, a magenta subpixel, and a yellow subpixel, which are capable of expressing white in combination.

The first substrate 100 may be provided with pixel driving lines together with the plurality of unit pixels UP in the display area AA.

A buffer layer may be disposed between the first substrate 100 and the plurality of unit pixels UP. The buffer layer may minimize diffusion of moisture or impurities from the first substrate 100 to the upper portion of the first substrate 100. The buffer layer may be configured by a single layer or a double layer of silicon oxide (SiOx) or silicon nitride (SiNx), but is not limited thereto.

The pixel driving lines are provided on a front surface of the first substrate 100 and configured to supply signals required for each of the plurality of subpixels SP1, SP2, and SP3. According to one or more exemplary aspects, the pixel driving lines may, for example, include a plurality of gate lines GL, a plurality of data lines DL, a plurality of driving power lines PL, a plurality of common power lines CL and the like.

The plurality of gate lines GL may extend in the first direction (e.g., X-axis direction) on the front surface of the first substrate 100 and may be spaced apart from each other in the second direction (e.g., Y-axis direction). Each of the plurality of gate lines GL may supply a scan signal to the plurality of subpixels SP1, SP2, and SP3.

The plurality of data lines DL may be disposed to intersect the plurality of gate lines GL on the front surface of the first substrate 100 to define the plurality of subpixels SP1, SP2, and SP3. The plurality of data lines DL may extend in the second direction (e. g., Y-axis direction) and may be spaced apart from each other in the first direction (e. g., X-axis direction). Each of the plurality of data lines DL may supply a data voltage to the plurality of subpixels SP1, SP2, and SP3.

The plurality of driving power lines PL may be arranged in parallel with the plurality of data lines DL on the front surface of the first substrate 100. Each of the plurality of driving power lines PL may supply a pixel driving power provided from the outside to the adjacent subpixels SP1, SP2, and SP3.

The plurality of common power lines CL may be arranged in parallel with each of the plurality of gate lines GL on the front surface of the first substrate 100. Each of the plurality of common power lines CL may supply common power provided from the outside to the adjacent subpixels SP1, SP2, and SP3. However, the present disclosure is not limited thereto. For example, the plurality of common power lines CL may also be arranged in parallel with the plurality of data lines DL, may extend in the second direction (e.g., Y-axis direction) and may be spaced apart from each other in the first direction (e.g., X-axis direction).

Each of the subpixels SP1, SP2, and SP3 is provided in a subpixel area defined by the gate line GL and the data line DL. Each of the plurality of subpixels SP1 to SP3 may be defined as a minimum unit area in which light is emitted virtually.

According to one or more exemplary aspects, the light emitting diode display device may further include a scan driver and a panel driver 400.

The scan driver generates a scan pulse according to a gate control signal inputted from the panel driver 400 and supplies the scan pulse to the gate line GL. The scan driver may be provided in the non-display area at the left and/or right side of the display area AA or may be provided in the display area AA. The scan driver may be provided in the arbitrary non-display area IA or display area AA capable of supplying the scan pulse to the gate line GL. The scan driver may be formed by a gate driver in panel GIP method, a gate driver in active area GIA method, or a tape automated bonding TAB method, or connected to a conductive pad such as a bonding pad of the display panel by a chip on glass COG or chip on panel COP method or may be connected with the display panel according to a chip on film COF method.

The panel driver 400 is connected to a pad portion prepared in the non-display area IA of the first substrate 100 and is configured to display an image corresponding to image data supplied from a host system on the display area AA. The panel driver 400 according to one or more exemplary aspects may include a plurality of data flexible circuit films 410, a plurality of data driving integrated circuits 420, a printed circuit board 430, a timing controller 440, and a power circuit 450. The panel driver 400 is connected to one side of the first substrate 100 in FIG. 1, however, but aspects of the present disclosure are not limited thereto, the panel driver 400 may be disposed at both sides of the first substrate 100.

Each of the plurality of data flexible circuit films 410 may be attached to the pad portion of the first substrate 100 provided at a periphery portion of the first substrate 100 by a film attaching process. Each of the plurality of data driving integrated circuits 420 may be individually mounted on each of the plurality of data flexible circuit films 410. The data driving integrated circuit 420 receives pixel data and a data control signal provided from the timing controller 440, converts the pixel data into a data voltage for each pixel in an analog form according to the data control signal, and supplies the data voltage to the corresponding data line DL.

The timing controller 440 is mounted on the printed circuit board 430 and receives image data and a timing synchronization signal provided from the host system. The timing controller 440 generates pixel data by aligning image data to be suitable for a pixel arrangement structure of the display area AA based on the timing synchronization signal, and provides the generated pixel data to the data driving integrated circuit 420. In addition, the timing controller 440 may generate each of a data control signal and a gate control signal based on the timing synchronization signal to control the driving timing of each of the plurality of data driving integrated circuits 420 and the scan driver.

The power supply circuit 450 is mounted on the printed circuit board 430 and generates various voltages necessary for displaying an image in the display area AA by using an input power input from the outside and supplies the generated voltages to a corresponding configuration.

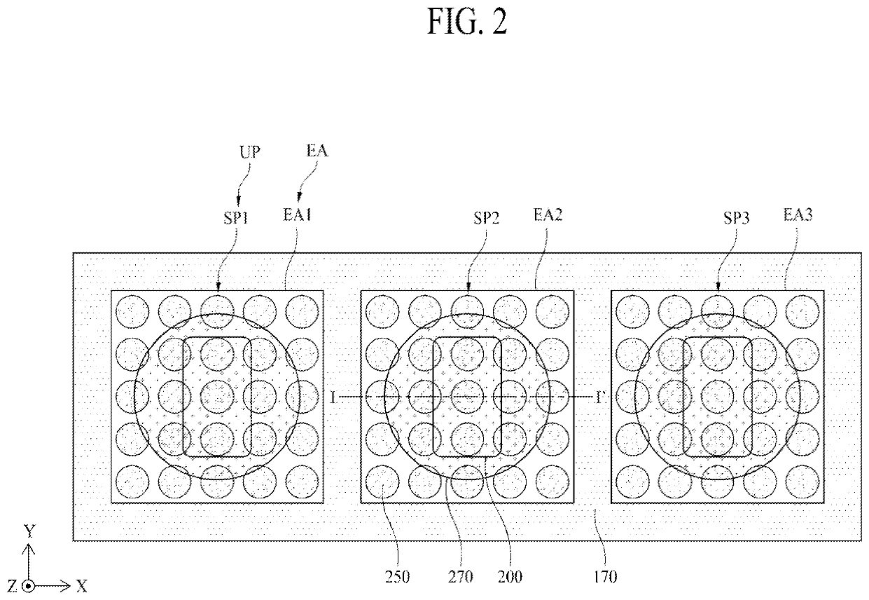

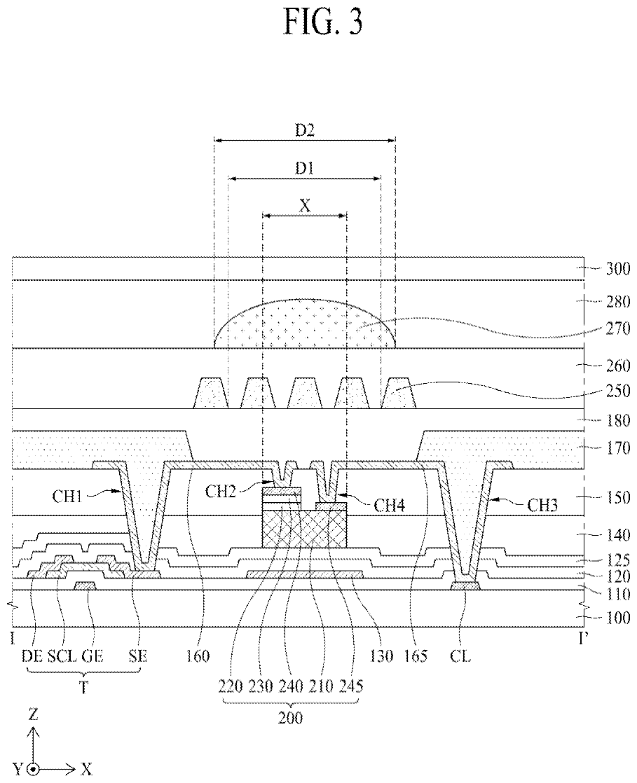

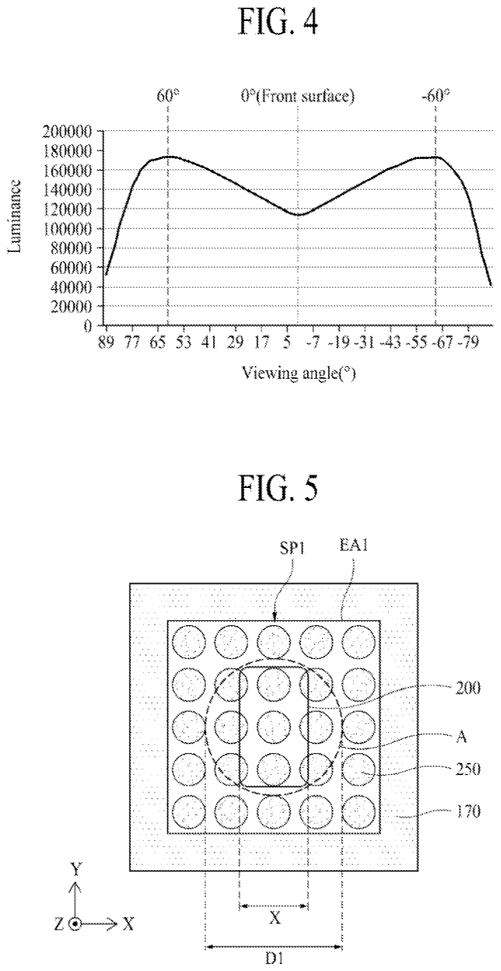

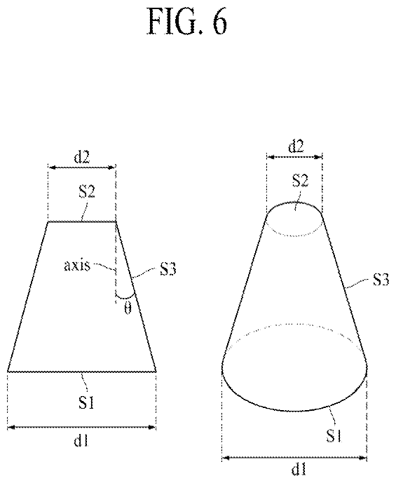

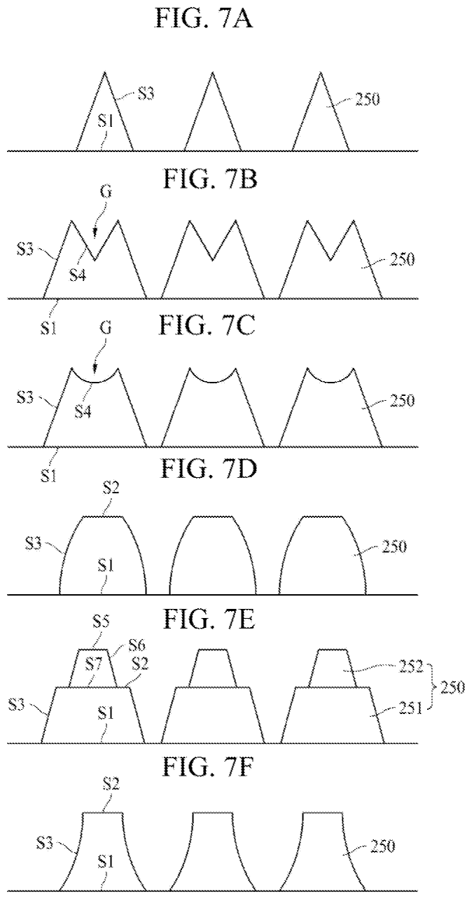

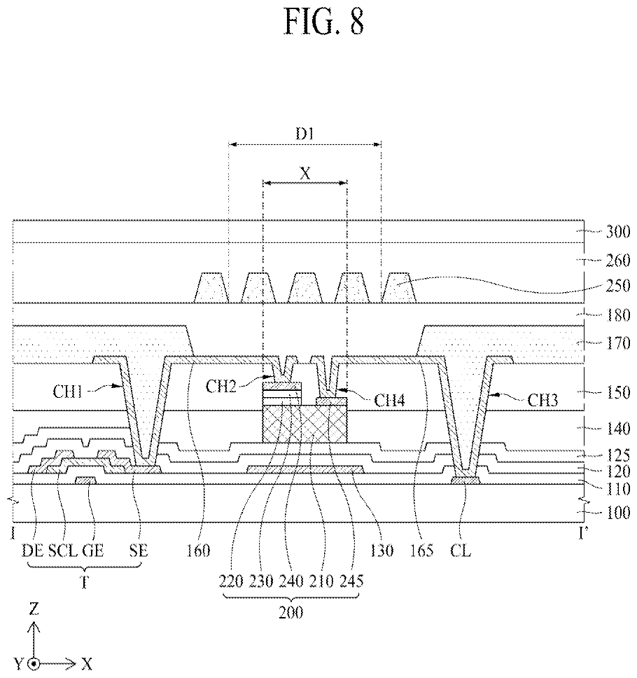

FIG. 2 is a plan view illustrating one example of a unit pixel included in a display area, FIG. 3 is an example of a cross sectional view taken along line I-I′ of FIG. 2, and FIG. 4 is a diagram illustrating one example of a luminance distribution for each viewing angle of light emitted from a light emitting diode. FIG. 5 is a plan view illustrating an effective area in a light emitting area, FIG. 6 illustrates one example of a shape of a low refractive pattern, and FIG. 7 illustrates modified examples of a shape of a low refractive pattern. FIG. 8 is another example of a cross sectional view taken along line I-I′ of FIG. 2.

A light emitting diode display device according to one or more exemplary aspects of the present disclosure includes a plurality of unit pixels of a display area AA, and each of the plurality of unit pixels includes a first subpixel SP1, a second subpixel SP2, and a third subpixel SP3, as shown in FIG. 2.

The first subpixel SP1 may include a first light emitting area EA1 emitting first color light, the second subpixel SP2 may include a second light emitting area EA2 emitting second color light, and the third subpixel SP3 may include a third light emitting area EA3 emitting third color light.

For example, all first to third light emitting areas EA1, EA2, and EA3 may emit light of different colors. For example, the first light emitting area EA1 may emit red light, the second light emitting area EA2 may emit green light, and the third light emitting area EA3 may emit blue light. In addition, an arrangement order of the respective subpixels SP1, SP2, and SP3 may be variously changed, and the color of light is not limited to the above-mentioned color.

According to one or more exemplary aspects, each of the plurality of unit pixels may further include a white subpixel for emitting white light to improve a luminance.

Meanwhile, FIG. 2 discloses that each unit pixel UP includes one of the first subpixel SP1, one of the second subpixel SP2, and one of the third subpixel SP3, but not limited thereto. According to another exemplary aspect, the unit pixel UP may be provided with two or more of at least one of the first subpixel SP1, the second subpixel SP2, and the third subpixel SP3. As one example, one unit pixel UP may include two of the first subpixels SP1, one of the second subpixel SP2, and one of the third subpixel SP3.

Each of the plurality of subpixels SP1, SP2, and SP3 includes a pixel circuit. The pixel circuit may be provided in a circuit area defined in the subpixels SP1, SP2, and SP3 and may be connected to an adjacent gate line GL, an adjacent data line DL, and an adjacent driving power line PL. The pixel circuit may control a current flowing in a light emitting diode 200 according to a data signal from the data line DL in response to a scan pulse from the gate line GL based on a pixel driving power supplied from the driving power line PL. The pixel circuit may include at least one transistor and a capacitor. But aspects of the present disclosure are not limited thereto, the pixel circuit may include more transistors and more capacitors, for example, 2T1C structure, 3T1C structure, 4T1C structure, 4T2C structure and etc. are also possible.

The at least one transistor may include a driving transistor T and switching transistors. The switching transistor may be switched according to the scan pulse supplied to the gate line GL to charge the capacitor with a data voltage supplied from the data line DL. Each of the driving transistor T and switching transistors may be embodied as a PMOS transistor which turns on when the gate voltage is at a low level, while Each of the driving transistor T and switching transistors may be embodied as a NMOS transistor which turns on when the gate voltage is at a high level.

The driving transistor T is switched according to the voltage supplied from the switching transistor or the data voltage charged in the capacitor, thereby generating a data current from power source supplied from the driving power line PL and supplying the data current to the light emitting diode 200 of the subpixels SP1, SP2, and SP3.

As shown in FIG. 3, the light emitting diode display device may include at least one of the driving transistor T, a plurality of insulating layers, the light emitting diode 200, a first connection electrode 160, a second connection electrode 165, a pattern 250, a planarization layer 260, a lens 270, and a planarization layer 280 over the first substrate 100. However, aspects of the present disclosure are not limited thereto, and one or more components within the light emitting diode display device may be omitted. For example, the planarization layer 280 may be omitted, or both the lens 270 and the planarization layer 280 may be omitted. All the components of each display device according to all aspects of the present disclosure are operatively coupled and configured.

The driving transistor T may include a gate electrode GE, a semiconductor layer SCL, a source electrode SE, and a drain electrode DE. Specifically, the gate electrode GE of the driving transistor T may be provided over the first substrate 100. The gate electrode GE may be formed on the same layer as the gate line GL, but not limited thereto. The gate electrode GE may be formed on a layer different from the gate line GL. The gate electrode GE may be formed of a single layer or multilayers of molybdenum (Mo), aluminum (Al), chromium (Cr), gold (Au), titanium (Ti), nickel (Ni), neodymium (Nd), copper (Cu), or an alloy thereof. The driving transistor T is formed by a bottom gate method, but the present disclosure is not limited thereto, the driving transistor T may be fabricated by top gate method or dual gate method.

A gate insulating layer 110 may be provided over the gate electrode GE. The gate insulating layer 110 may include single inorganic layer, for example, a silicon oxide layer (SiOx), a silicon nitride layer (SiNx), or a multilayer thereof.

The semiconductor layer SCL of the driving transistor T may be provided over the gate insulating layer 110 and may overlap with the gate electrode GE. The semiconductor layer SCL may include a silicon-based semiconductor material or an oxide-based semiconductor material. For example, the oxide-based semiconductor material may be formed of one of indium gallium zinc oxide (IGZO), indium zinc oxide (IZO), indium gallium tin oxide (IGTO), and indium gallium oxide (IGO), but is not limited thereto, and silicon-based semiconductor material may be polycrystalline silicon semiconductor layer.

The source electrode SE and the drain electrode DE of the driving transistor T may be provided over the semiconductor layer SCL. At least a portion of the source electrode SE of the driving transistor T may overlap with one side of the semiconductor layer SCL, and at least a portion of the drain electrode DE may overlap with the other side of the semiconductor layer SCL. The source electrode SE and the drain electrode DE of the driving transistor T may be formed on the same layer as the data line DL and the driving power line PL in the same process, but not limited thereto. The source electrode SE and the drain electrode DE of the driving transistor T may be formed on a layer different from the data line DL and the driving power line PL. The source electrode SE and the drain electrode DE of the driving transistor T may be formed as a single layer or multiple layers of molybdenum Mo, aluminum Al, chromium Cr, gold Au, titanium Ti, nickel Ni, neodymium Nd, copper Cu, or an alloy thereof.

An insulating interlayer 120 may be provided over the source electrode SE and the drain electrode DE of the driving transistor T. The insulating interlayer 120 may be provided to cover the driving transistor T. The insulating interlayer 120 may include an inorganic layer, for example, a silicon oxide layer (SiOx), a silicon nitride layer (SiNx), or a multi-layer thereof which is made of silicon oxide (SiOx) or silicon nitride (SiNx). In particular, the insulating interlayer 120 may include a silicon nitride (SiNx) layer containing hydrogen particles, or the insulating interlayer 120 may include an organic material such as acryl resin, epoxy resin, phenolic resin, polyamide resin, and polyimide resin. The insulating interlayer 120 is omittable.

A first planarization layer 140 may be provided over the insulating interlayer 120. The first planarization layer 140 is provided to cover the driving transistor T, thereby protecting the driving transistor T and planarizing a step difference caused by the driving transistor T. The first planarization layer 140 may include an organic film such as acryl resin, epoxy resin, phenolic resin, polyamide resin, polyimide resin, etc.

A groove, hole, opening, or concave portion may be provided in a region corresponding to the light emitting area EA1, EA2, and EA3 of the subpixel SP1, SP2, and SP3 in the first planarization layer 140. The light emitting diode 200 may be accommodated in the groove, hole, opening, or concave portion provided in the first planarization layer 140 and may be electrically connected to the driving transistor T and the common power line CL. The light emitting diode 200 may emit light by the current flowing from the driving transistor T to the common power line CL.

The light emitting diode 200 includes a first semiconductor layer 210, an active layer 220, a second semiconductor layer 230, a first electrode 240, and a second electrode 245. Even though it is described in the present specification that the light emitting diode 200 has a lateral structure in which the first electrode 240 and the second electrode 245 are disposed in parallel on an upper surface of the light emitting diode 200, it is not necessarily limited thereto. For example, the light emitting diode 200 may have a vertical structure in which the first electrode 240 and the second electrode 245 are disposed on different surfaces or a flip structure in which the first electrode 240 and the second electrode 245 are disposed on the same surface.

The first semiconductor layer 210 provides negative charges such as electrons to the active layer 220. According to one or more exemplary aspects, the first semiconductor layer 210 may include an n-GaN-based semiconductor material, and the n-GaN-based semiconductor material may be GaN, AlGaN, InGaN, or AlInGaN. For example, impurities used for doping the first semiconductor layer 210 may be silicon (Si), germanium (Ge), tin (Sn) selenium (Se), tellurium (Te), or carbon (C).

The active layer 220 may be provided over one side of the first semiconductor layer 210. The active layer 220 has a single-layer or a multi-quantum well (MQW) structure having a well layer and a barrier layer having a band gap higher than that of the well layer. According to one or more exemplary aspects, the active layer 220 may have a multiple quantum well structure such as InGaN/GaN.

The second semiconductor layer 230 is provided over the active layer 220 and is configured to provide positive charges such as holes to the active layer 220. According to one or more exemplary aspects, the second semiconductor layer 230 may include a p-GaN-based semiconductor material, and the p-GaN-based semiconductor material may be GaN, AlGaN, InGaN, or AlInGaN. For example, impurities used for doping the second semiconductor layer 230 may be one of magnesium (Mg), zinc (Zn), beryllium (Be), or the like.

In addition, the first semiconductor layer 210, the active layer 220, and the second semiconductor layer 230 may be sequentially stacked over a semiconductor substrate. The semiconductor substrate includes a semiconductor material such as sapphire, gallium nitride (GaN), silicon (Si), silicon carbide (SiC), or the like, but is not limited thereto. The semiconductor substrate may be used as a growth substrate for growing each of the first semiconductor layer 210, the active layer 220, and the second semiconductor layer 230, and then may be separated from the first semiconductor layer 210 by a substrate separation process. The substrate separation process may be laser lift-off or chemical lift-off. Accordingly, as the semiconductor substrate for growth is removed from the light emitting diode 200, the light emitting diode 200 may have a relatively small thickness.

The first electrode 240 may be provided over the second semiconductor layer 230 and may be electrically connected to the source electrode SE of the driving transistor T. The first electrode 240 may correspond to an anode terminal.

The second electrode 245 may be provided over the other side of the first semiconductor layer 210, along X direction, to be electrically separated from the active layer 220 and the second semiconductor layer 230. The second electrode 245 may be electrically connected to the common power line CL. The second electrode 245 may be a cathode terminal.

The first electrode 240 and the second electrode 245 may include a material including at least one of a metal material such as Au, W, Pt, Si, Ir, Ag, Cu, Ni, Ti, and Cr, or an alloy thereof, or may include a transparent conductive material such as Indium Tin Oxide ITO or Indium Zinc Oxide IZO, but not limited thereto.

In another example, an encapsulating layer or an insulating layer may be disposed on the first semiconductor layer 210 and the second semiconductor layer 230 to protect the first semiconductor layer 210 and the second semiconductor layer 230. The encapsulating layer may include SiO₂, Si₃N₄, or resin. The encapsulating layer may be disposed on the entire surface of the light emitting diode 200 excluding the lower portion of the light emitting diode 200. However, parts of the first electrode 240 and the second electrode 245 are exposed by the encapsulating layer and the first electrode 240 and the second electrode 245 may be in ohmic contact with the first connection electrode 160 and the second connection electrode 165, respectively, through the exposed area.

The light emitting diode 200 may emit light by recombination of electrons and holes according to the current flowing between the first electrode 240 and the second electrode 245. The light generated by the light emitting diode 200 passes through each of the first electrode 240 and the second electrode 245 and is emitted to the outside, to thereby display an image.

The light emitting diode 200 may be mounted on each of the first subpixel SP1, the second subpixel SP2, and the third subpixel SP3. The light emitting diode 200 may include a first light emitting diode mounted on the first subpixel SP1, a second light emitting diode mounted on the second subpixel SP2, and a third light emitting diode mounted on the third subpixel SP3. For example, the light emitting diode 200 may include a red light emitting diode mounted on the red subpixel SP1, a green light emitting diode mounted on the green subpixel SP2, and a blue light emitting diode mounted on the blue subpixel SP3. The unit pixel UP may further include a white subpixel. In this case, the light emitting diode 200 may further include a white light emitting diode mounted on the white subpixel.

According to another example, the light emitting diode 200 may include a white light emitting diode mounted on each of the first to third subpixels SP1, SP2, and SP3. In this case, the light emitting diode display device may further include a color filter layer overlapping with each of the first to third subpixels SP1, SP2, and SP3. The color filter layer may transmit only light having a wavelength of a color corresponding to the corresponding subpixel among white light emitted from the white light emitting diode. Further, the type and the number of light emitting diodes which configure the first to third subpixels SP1, SP2, and SP3 may be configured in various ways according to the exemplary aspect.

For example, one or more light emitting diodes 200 may be mounted on each of a first subpixel SP1, a second subpixel SP2, and a third subpixel SP3. For example, the unit pixel UP may include two of the first subpixels SP1, one of the second subpixel SP2, and one of the third subpixel SP 3. Each of the two first subpixels SP1 may include one pixel circuit and one first light emitting diode. Meanwhile, one of the pixel circuit and two of the second light emitting diodes are provided in one of the second subpixel SP2, and two of the second light emitting diodes may share one pixel circuit. In addition, one of the pixel circuit and two of the third light emitting diodes may be provided in one of the third subpixel SP3, and two of the third light emitting diodes may share one pixel circuit. In the present specification, when two light emitting diodes emit the same color light, it means that the light emitting diodes are manufactured to have the same design to emit the same color light. For example, when the material which configures the light emitting diodes and the laminated structure are the same, it may be defined that two light emitting diodes emit the same color light. At this time, even though the color of the light emitted by the light emitting diode is changed due to the manufacturing deviation of the light emitting diode or a long used time, if it is determined that they are designed to emit the same color light at the initial manufacturing, it may be defined that two light emitting diodes emit the same color light.

According to one or more exemplary aspects of the present disclosure, the light emitting diode display device may further comprise a reflective layer 130 between the light emitting diode 200 and the first substrate 100 with the gate insulating layer 110 interposed therebetween. The reflective layer 130 is a layer for improving a luminous efficiency of the light emitting diode 200. The reflective layer 130 reflects light directed to the first substrate 100, among light emitted from the light emitting diode 200, toward the upper portion of the display device to be output to the outside of the display device. The reflective layer 130 may be provided to overlap with the light emitting area EA including the light emitting diode 200. As shown in FIG. 3, the reflective layer 130 may be formed of the same or substantially same material as the source/drain electrodes SE/DE of the driving thin film transistor T and may be provided on the same layer as the source/drain electrodes SE/DE, but not limited thereto. The reflective layer 101 may be formed of the same or substantially same material as the gate electrode GE of the driving thin film transistor T and may be provided on the same layer as the gate electrode GE. For example, the reflective layer 130 may be formed of a metal material having a high reflectance, and for example, may include silver (Ag) or aluminum (Al). In the meantime, pure silver (Ag) may react with oxygen or nitrogen so that the reflectance may be lowered. Therefore, the reflective layer 130 may be formed of a multiple layer of ITO/Ag/ITO or formed by adding impurities such as palladium (Pd) or copper (Cu). Also, the reflective layer 130 may be disposed on the insulating interlayer 120, may be electrically connected to the source/drain electrodes SE/DE of the driving thin film transistor T, and may be formed of a material different from that of the source/drain electrodes SE/DE, but not limited thereto.

The reflective layer 130 may reflect light incident from the light emitting diode 200 toward the light emitting diode 200. Accordingly, the light emitting diode display device according to the present aspect may have a top emission structure by including the reflective layer 130. However, when the light emitting diode display device has a bottom emission structure or a dual emission structure, the reflective layer 130 may be omitted. Aspects of the present disclosure are not limited thereto.

The second planarization layer 150 may be provided to cover the light emitting diode 200 over the first planarization layer 140. The second planarization layer 150 may be provided to cover the upper surface of the first planarization layer 140 and the side surface and the upper surface of the light emitting diode 200 disposed in the groove of the first planarization layer 140. The second planarization layer 150 may provide a flat surface on the first planarization layer 140. Also, the second planarization layer 150 is buried in the peripheral space of the light emitting diode 200 disposed in the groove of the first planarization layer 140, to thereby fix the position of the light emitting diode 200.

The second planarization layer 150 may include an organic film such as photo acryl, acryl resin, epoxy resin, phenolic resin, polyamide resin, polyimide resin, benzocyclobutene resin, etc.

The first connection electrode 160 is provided over the second planarization layer 150 and is configured to electrically connect the first electrode 240 of the light emitting diode 200 and the source electrode SE of the driving transistor T. The first connection electrode 160 may be an anode electrode.

In an example, one side of the first connection electrode 160 may be electrically connected to the source electrode SE of the driving transistor T through a first contact hole CH1 passing through the insulating interlayer 120, the first planarization layer 140, and the second planarization layer 150. In another example, when an adhesive layer 125 is formed to cover the whole surface of the insulating interlayer 120, the first contact hole CH1 may also pass through the adhesive layer 125. The other side of the first connection electrode 160 may be electrically connected to the first electrode 240 of the light emitting diode 200 through a second contact hole CH2 provided in the second planarization layer 150. Accordingly, the first electrode 240 of the light emitting diode 200 may be electrically connected to the source electrode SE of the driving transistor T through the first connection electrode 160.

When the light emitting diode display device is a top emission type, the first connection electrode 160 is made of a transparent conductive material. When the light emitting diode display device is a bottom emission type, the first connection electrode 160 is made of a light reflective conductive material. For example, the transparent conductive material may be one of indium gallium tin oxide (IGTO), indium gallium oxide (IGO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO), Indium Tin Oxide (ITO) or Indium Zinc Oxide (IZO), but not limited thereto. The light reflective conductive material may be one of aluminum (Al), silver (Ag), gold (Au), platinum (Pt), copper (Cu), or the like, but not limited thereto. The first connection electrode 160 of the light reflective conductive material may be composed of a single layer including the light reflective conductive material or a multilayer in which the single layer is stacked.

The second connection electrode 165 is provided on the second planarization layer 150 and the light emitting diode 200 and is configured to electrically connect the second electrode 245 of the light emitting diode 200 and the common power line CL. The second connection electrode 165 may be a cathode electrode.

More specifically, one side of the second connection electrode 165 may be electrically connected to the common power line CL through a third contact hole CH3 passing through the gate insulating layer 110, the insulating interlayer 120, the first planarization layer 140, and the second planarization layer 150. In another example, when an adhesive layer 125 is formed to cover the whole surface of the insulating interlayer 120, the third contact hole CH3 may also pass through the adhesive layer 125. The other side of the second connection electrode 165 may be electrically connected to the second electrode 245 of the light emitting diode 200 through a fourth contact hole CH4 provided in the second planarization layer 150. Accordingly, the second electrode 245 of the light emitting diode 200 may be electrically connected to the common power line CL through the second connection electrode 165. The second connection electrode 165 may include the transparent conductive material or the reflective conductive material or may be formed of the same or substantially same material as the first connection electrode 160. For example, the reflective conductive material may be Al, Ag, Au, Pt, or Cu, but is not necessarily limited thereto.

The light emitting diode 200 may be attached to the upper surface of the insulating interlayer 120 by an adhesive layer 125. The adhesive layer 125 is provided between the insulating interlayer 120 and the light emitting diode 200, to thereby attach the light emitting diode 200 to the upper surface of the insulating interlayer 120. Accordingly, the position of the light emitting diode 200 may be fixed by the adhesive layer 125. However, the adhesive layer is not necessarily limited thereto, the adhesive layer 125 may be formed of a thermosetting material or a photo curing material and may be one of adhesive polymer, epoxy resist, UV resin, a polyimide-based material, an acrylate-based material, a urethane-based material, and polydimethylsiloxane (PDMA), but is not limited thereto. Also, it is to be noted that although the adhesive layer 125 is shown in FIG. 3 as covering the whole surface of the insulating interlayer 120, aspects of the present disclosure are not limited thereto. For example, the insulating layer 120 may be disposed in a region corresponding to the light emitting diode 200.

According to one or more exemplary aspects, the light emitting diode display device may further include a bank 170. The bank 170 may be provided over the second planarization layer 150 and may be configured to cover at least a portion of the first connection electrode 160 and at least a portion of the second connection electrode 165. The bank 170 may be provided to fill the first contact hole CH1 on the first connection electrode 160 provided in the first contact hole CH1. Also, the bank 170 may be provided to fill the third contact hole CH3 on the second connection electrode 165 provided in the third contact hole CH3.

The bank 170 may define the light emitting areas EA1, EA2, and EA3 of the respective subpixels SP1, SP2, and SP3. The bank 170 may include an opening area corresponding to the light emitting area EA1, EA2, and EA3 through which light emitted from the light emitting diode 200 is emitted to the outside. The light emitted from the light emitting diode 200 provided in each of the subpixels SP1, SP2, and SP3 may be emitted to the outside in the opening area of the bank 170. Accordingly, the light emitting area EA1, EA2, and EA3 of each of the subpixels SP1, SP2, and SP3 may correspond to the area in which the bank 170 is not formed.

Meanwhile, the bank 170 may include an organic film such as acryl resin, epoxy resin, phenolic resin, polyamide resin, polyimide resin, etc. The bank 170 may include a black material or a light absorbing material. For example, the bank 170 may include a carbon-based mixture and specifically, include carbon black. Accordingly, the light emitted from the light emitting diode 200 provided in each of the subpixels SP1, SP2, and SP3 may not be emitted to the outside by the absorption of light in the area where the bank 170 is formed. Accordingly, the area in which the bank 170 is formed may correspond to a non-emission area NEA. The bank 170 prevents or reduces the light emitted from the light emitting diode 200 from proceeding to the adjacent subpixels SP1, SP2, and SP3, thereby preventing or reducing color mixing between the subpixels SP1, SP2, and SP3. Accordingly, the display quality of the display device may be improved. In addition, the bank 170 is disposed in the first contact hole CH1 and the third contact hole CH3 to increase the light collection rate of the light emitting area and further improve the luminous efficiency. Further, heat concentrated on the light emitting diode 200 is absorbed by the bank 170 to be output to the outside and thus the lifespan of the display device may be extended.

The third planarization layer 180 may be provided on the bank 170 and the first and second connection electrodes 160 and 165. The third planarization layer 180 may be provided to cover a portion of the first connection electrode 160 and a portion of the second connection electrode 165, which are exposed without being covered by the bank 170 and the upper surface of the bank 170. The third planarization layer 180 may provide a flat surface on the bank 170. The third planarization layer 180 may also cover and contact an exposed portion of the second planarization layer 150 as shown in FIG. 3.

The third planarization layer 180 may include an organic film such as acryl resin, epoxy resin, phenolic resin, polyamide resin, and polyimide resin.

The pattern 250 is provided over the light emitting diode 200. The pattern 250 may be arranged within the light emitting area EA of each subpixel as a matrix form or an array form. This pattern 250 may have a first refractive index. The first refractive index is equal to or less than 1.5 and may be between 1.4 and 1.5. The pattern 250 may be include an organic material having the first refractive index. Hereinafter, the pattern 250 having the first refractive index is referred to as a low refractive pattern.

The low refractive pattern 250 is configured to change the path of light so that the light emitted from the light emitting diode 200 proceeds close to the front surface. For example, the front surface may indicate that a viewing angle is 0°. A case in which the viewing angle is 0° refers to a case in which the display device is view in a direction vertical to a surface of the display device.

The light generated by the light emitting diode 200 may have a luminance distribution of ‘M’ shape having a maximum luminance (which is also referred to as peak luminance) at a viewing angle greater than 0°. For example, as shown in FIG. 4, the light generated by the light emitting diode 200 may have a maximum luminance at a viewing angle of 60°. Thus, the luminance distribution of ‘M’ shape is inefficient because the luminance at the front surface (0°) is low. According to one or more exemplary aspects of the present disclosure, the light emitting diode display device includes the low refractive pattern 250 on the light emitting diode 200 so that it is possible to increase the luminance at the front surface (0°) by changing the path of light emitted from the light emitting diode 200.

Specifically, the low refractive pattern 250 may be provided over the third planarization layer 180 and may be configured to at least partially overlap with the light emitting diode 200. The plurality of low refractive patterns 250 are provided in each of the light emitting areas EA1, EA2, and EA3 of the plurality of subpixels SP1, SP2, and SP3 so that it is possible to change a portion of the light traveling to the outside from the light emitting diode 200.

As shown in FIG. 5, the plurality of low refractive patterns 250 may be provided in an effective area A of the light emitting areas EA1, EA2, and EA3. For example, the effective area A is included in each of the light emitting areas EA1, EA2, and EA3 of the plurality of subpixels SP1, SP2, and SP3. And the effective area A may correspond to an area in which a path of light may be changed to be closer to the front surface by the low refractive pattern 250. The effective area A may have a circular shape with a first diameter D1 with respect to the light emitting diode 200, however, the present disclosure is not limited thereto and the effective area A may have an ellipse or oval shape, or a quadrilateral shape, etc. In this case, the first diameter D1 may be twice the short-axis length X of the light emitting diode 200.

The low refractive pattern 250 may be arranged in the array of the first direction (e.g., X-axis direction) and the second direction (e.g., Y-axis direction) in the light emitting area EA1, EA2, and EA3. In this case, the plurality of low refractive patterns 250 may be provided in the first direction (e.g., X-axis direction), and the plurality of low refractive patterns 250 may be provided in the second direction (e.g., Y-axis direction). The low refractive patterns 250 disposed in the light emitting areas EA1, EA2, and EA3 may be spaced apart from each other, but not limited thereto. The low refractive patterns 250 may be arranged while being in contact with each other in the light emitting areas EA1, EA2, and EA3.

According to one or more exemplary aspects of the present disclosure, at least three low refractive patterns 250 may be arranged in the effective area A in the X-axis vertical cross section. According as the number of low refractive patterns 250 disposed in the effective area A is increased, the ratio of light emitted to the front surface may be increased in the light traveling from the light emitting diode 200 to the outside. Thus, in the light emitting diode display device according to one or more exemplary aspects of the present disclosure, at least three low refractive patterns 250 are arranged in the effective area A in the vertical cross section, thereby improving the front luminance by the low refractive pattern 250.

Meanwhile, since the light incident on the bank 170 among the light emitted from the light emitting diode 200 is not emitted to the outside, the low refractive pattern 250 may not be provided in the non-emission area NEA provided with the bank 170. For example, the low refractive pattern 250 may be provided in the opening area of the bank 170.

The low refractive pattern 250 may include an inclined surface to change the path of light. Specifically, the low refractive pattern 250 may have a truncated shape as shown in FIG. 6. In FIG. 6, the low refractive pattern 250 is shown in a truncated cone shape, but not limited thereto. The low refractive pattern 250 may have a polygonal pyramid shape.

The low refractive pattern 250 may include a lower surface S1, an upper surface S2, and a side surface S3 for connecting the lower surface S1 and the upper surface S2 to each other. In the low refractive pattern 250, a diameter d1 of the lower surface S1 is greater than a diameter d2 of the upper surface S2, whereby the side surface S3 may be an inclined surface.

The inclined surface S3 of the low refractive pattern 250 may have a taper angle θ of 5° to 40°. In this case, the taper angle θ is an angle formed by an axis and a base line and may correspond to an angle formed by the inclined surface S3 and the axis, for example, Z-axis. In the inclined surface S3 of the low refractive pattern 250, the taper angle θ may be determined in consideration of the luminance distribution for each viewing angle of the light emitting diode 200. Specifically, in the inclined surface S3 of the low refractive pattern 250, the taper angle θ may be determined based on a first viewing angle having a maximum luminance distribution of the light generated by the light emitting diode 200. The inclined surface S3 of the low refractive pattern 250 may have the taper angle θ capable of totally reflecting the light of the first viewing angle emitted from the light emitting diode 200.

As one example, the light emitting diode 200 may have a maximum light intensity, for example, a maximum luminance, at a viewing angle of about 60°. The low refractive pattern 250 may have the inclined surface S3 having the taper angle θ of about 20°. At this time, the light having a viewing angle of about 60° emitted from the light emitting diode 200 is totally reflected from the inclined surface S3 of the low refractive pattern 250 and emitted to the front surface 0°.

As the low refractive pattern 250 has the taper angle θ capable of totally reflecting the light of the first viewing angle having the maximum luminance, it is possible to change the path of the large amount of light to the front direction (0°). Accordingly, the light emitting diode display device according to one or more exemplary aspects of the present disclosure may greatly improve the luminance at a viewing angle of 0°, for example, the front surface, and may overcome, address or reduce the inefficient luminance distribution. Therefore, the light emitting diode display device according to one or more exemplary aspects of the present disclosure may have a more uniform and efficient luminance distribution.

On the other hand, FIG. 3 and FIG. 6 show that the low refractive pattern 250 has a truncated shape, but not necessarily limited thereto. The low refractive pattern 250 may have various shapes shown in FIG. 7.

For example, as shown in FIG. 7A, the low refractive pattern 250 may have a conical shape, but not limited thereto. The low refractive pattern 250 may have a polygonal pyramid shape. In this case, the low refractive pattern 250 may include only lower and side surfaces S1 and S3 without an upper surface, and the side surface S3 may have an inclined surface. When the low refractive pattern 250 has the conical shape, a diameter of the lower surface S1 may be reduced, whereby the number of the low refractive patterns 250 arranged in the effective area A in the light emitting areas EA1, EA2, and EA3 may be increased. Also, the low refractive pattern 250 may increase the area of the inclined surface S3. In the light emitting diode display device with the low refractive pattern 250 having the conical shape as shown in FIG. 7A, the number of low refractive patterns 250 increases and the area of the inclined surface S3 of the low refractive pattern 250 on which the light is incident increases, so that it is possible to improve the luminance on the front surface.

As another example, as shown in FIG. 7B and FIG. 7C, the low refractive pattern 250 may be provided with a groove G in an upper surface S4. The low refractive pattern 250 includes a lower surface S1, the upper surface S4, and a side surface S3 for connecting the lower surface S1 and the upper surface S4, and the side surface S3 may be an inclined surface. The low refractive pattern 250 may be provided with the groove G in a triangular shape on the upper surface S4 as shown in FIG. 7B or may be provided with the groove G in shape of concave lens on the upper surface as shown in FIG. 7C. When the groove G is provided on the upper surface S4, the low refractive pattern 250 may concentrate the light coming into the inside thereof. Accordingly, as shown in FIG. 7B and FIG. 7C, the light emitting diode display device with the low refractive pattern 250 having the groove G on the upper surface S4 collects the light entering the low refractive pattern 250, thereby additionally improving the luminance on the front surface.

As another example, the side surface S3 of the low refractive pattern 250 may not be inclined at a predetermined angle. The side surface S3 of the low refractive pattern 250 may be convexly formed as shown in FIG. 7D or may be concavely formed as shown in FIG. 7F.

As another example, the low refractive pattern 250 may be composed of a plurality of layers. As shown in FIG. 7E, the low refractive pattern 250 may include a first layer 251 and a second layer 252 on the first layer 251. Each of the first layer 251 and the second layer 252 may have a truncated shape. The first layer 251 includes a lower surface S1, an upper surface S2, and a side surface S3 for connecting the lower surface S1 and the upper surface S4 to each other, and the side surface S3 may be an inclined surface. When the second layer 252 includes an upper surface S5, a lower surface S7 being in contact with the upper surface S2 of the first layer 251, and a side surface S6 for connecting the upper surface S5 and the lower surface S7 to each other, and the side surface S6 may be an inclined surface.

In addition to the shapes illustrated in FIG. 7, the low refractive pattern 250 may be transformed into various shapes with the side surface S3 being the inclined surface.

The planarization layer 260 may be provided over the low refractive pattern 250 and is configured to cover the low refractive pattern 250. The planarization layer 260 may planarize the step difference caused by the low refractive pattern 250. The planarization layer 260 may include an organic material whose refractive index is higher than that of the low refractive pattern 250. For example, the planarization layer 260 may have a second refractive index greater than the first refractive index. The second refractive index may be greater than 1.5 and may be 1.6 or more. Hereinafter, the planarization layer 260 having the second refractive index is referred to as a high refractive planarization layer 260.

In the light emitting diode display device according to one or more exemplary aspects of the present disclosure, the high refractive planarization layer 260 has the second refractive index which is larger than that of the low refractive pattern 250, so that light incident on the inclined surface S3 of the low refractive pattern 250 in the light emitting diode 200 may be totally reflected on the inclined surface of the low refractive pattern 250. In the light emitting diode display device according to one or more exemplary aspects of the present disclosure, the high refractive planarization layer 260 may include an organic material having a high refractive index, thereby increasing the amount of light totally reflected on the inclined surface S3 of the low refractive pattern 250. Accordingly, the light emitting diode display device according to one or more exemplary aspects of the present disclosure may maximize or increase the luminance on the front surface.

Also, the light emitting diode display device according to one or more exemplary aspects of the present disclosure may increase the light collection effect of the lens 270 by securing an optical distance between the light emitting diode 200 and the lens 270 through the high refractive planarization layer 260.

The lens 270 may be provided over the high refractive planarization layer 260 while being convex toward the second substrate 300. The lens 270 may include an organic material having a refractive index which is higher than that of the low refractive pattern 250. For example, the lens 270 may have a third refractive index which is greater than the first refractive index. The third refractive index may be greater than 1.5 and may be 1.6 or more. The lens 270 may have a different refractive index from the high refractive planarization layer 260, but not limited thereto. The lens 270 may have the same or substantially same refractive index as the high refractive planarization layer 260. Hereinafter, the lens 270 having the third refractive index is referred to as a high refractive lens.

The high refractive lens 270 may be provided to at least partially overlap with the light emitting diode 200 provided in each of the sub pixels SP1, SP2, and SP3. The high refractive lens 270 may be arranged to correspond to the light emitting diode 200 by a one-to-one correspondence. In addition, the high refractive lens 270 may be provided to at least partially overlap with the plurality of low refractive patterns 250 disposed in the light emitting areas EA1, EA2, and EA3 of each of the subpixels SP1, SP2, and SP3. For example, one high refractive lens 270 may be arranged to correspond to the plurality of low refractive patterns 250.

The high refractive lens 270 may concentrate the light generated by the corresponding light emitting diode 200. More specifically, the light generated from the light emitting diode 200 is totally reflected or refracted by the low refractive pattern 250, and the light whose path is changed by the total reflection or refraction may pass through the high refractive planarization layer 260. Alternatively, some of the light generated from the light emitting diode 200 may directly pass through the high refractive planarization layer 260 without meeting the low refractive pattern 250. The high refractive lens 270 receives the light transmitted through the high refractive planarization layer 260, collects the incident light, and emits the collected light to the outside.

The high refractive lens 270 may have the diameter D2 greater than the diameter D1 of the effective area A. For example, the diameter D2 of the high refractive lens 270 may be greater than the length of the long axis direction of the light emitting diode 200.

The planarization layer 280 may be provided over the high refractive lens 279 and may be configured to cover the high refractive lens 270. The planarization layer 280 may planarize the step difference generated by the high refractive lens 270. The planarization layer 280 may include an organic material whose refractive index is lower than that of the high refractive lens 270. For example, the planarization layer 280 may have a fourth refractive index which is lower than the third refractive index. The fourth refractive index is equal to or less than 1.5 and may be between 1.4 and 1.5. Hereinafter, the planarization layer 280 having the fourth refractive index is referred to as a low refractive planarization layer 280.

In the light emitting diode display device according to one or more exemplary aspects of the present disclosure, the low refractive planarization layer 280 has a fourth refractive index which is smaller than that of the high refractive lens 270, so that the light passing through the high refractive lens 270 may be refracted from the convex surface of the high refractive lens 270 to the front direction (viewing angle 0°). The light emitting diode display device according to one or more exemplary aspects of the present disclosure may further improve the light collection effect of the high refractive lens 270 by forming the low refractive planarization layer 280 of an organic material having a low refractive index. Accordingly, the light emitting diode display device according to one or more exemplary aspects of the present disclosure may maximize or increase the luminance at the front surface (viewing angle 0°).

The second substrate 300 is disposed to cover other portions except for the pad portion of the first substrate 100 and is configured to protect a pixel array provided on the first substrate 100. The second substrate 300 may be defined as an opposite substrate, an encapsulation substrate, or a color filter array substrate. The second substrate 300 may include a transparent glass material or a transparent plastic material, but not limited thereto.

FIG. 3 shows that the light emitting diode display device includes the high refractive lens 270 and the low refractive planarization layer 280 to improve the luminance at the front direction (i.e., viewing angle 0°), but not necessarily limited thereto. As another exemplary aspect, the light emitting diode display device may omit the high refractive lens 270 and the low refractive planarization layer 280 as shown in FIG. 8. In this case, the light emitting diode display device may reflect or refract the light generated from the light emitting diode 200 by the low refractive pattern 250 and may transmit the totally reflected or refracted light to the outside through the high refractive planarization layer 260 and the second substrate 300.

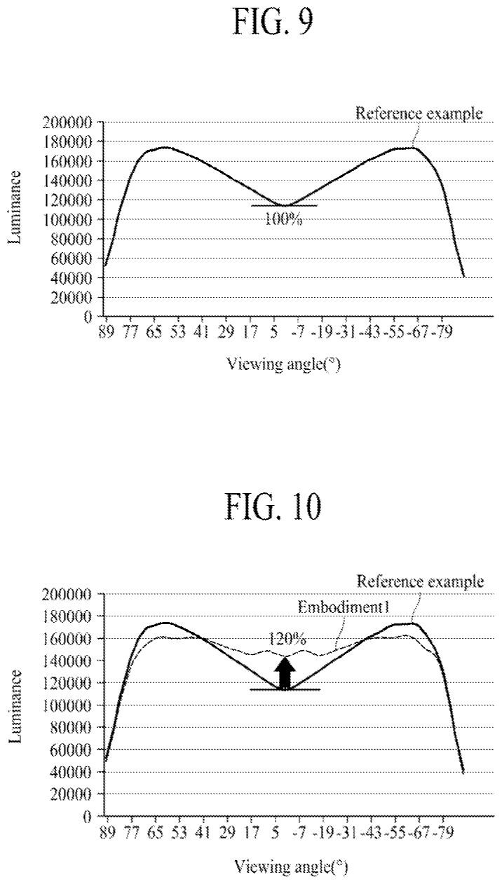

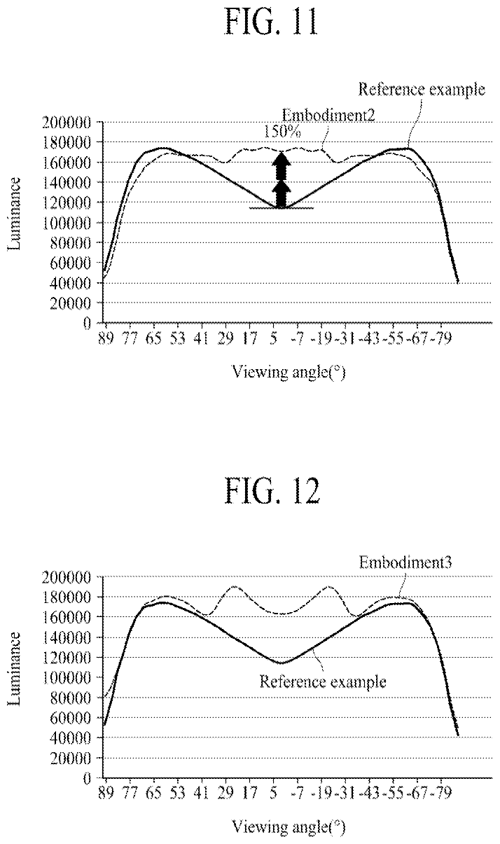

FIG. 9 shows a luminance distribution for each viewing angle of a light emitting diode display device according to a reference example in which a low refractive pattern and a high refractive lens are not provided, FIG. 10 shows a luminance distribution for each viewing angle of a light emitting diode display device according to Aspect 1 provided with a low refractive pattern, and FIG. 11 shows a luminance distribution for each viewing angle of a light emitting diode display device according to Aspect 2 provided with a low refractive pattern and a high refractive lens.

The light emitting diode display device according to the reference example may have a structure in which the low refractive pattern 250, the high refractive planarization layer 260, the high refractive lens 270, and the low refractive planarization layer 280 are omitted from the light emitting diode display device shown in FIG. 3.

The light emitting diode display device according to the reference example may emit the light generated from the light emitting diode 200 to the outside through the second substrate 300 without being reflected or refracted. Accordingly, the light emitting diode display device according to the reference example may have a luminance distribution of ‘M’ shape having a maximum luminance at a viewing angle greater than 0°, similarly to a luminance distribution for each viewing angle of light generated by the light emitting diode 200, as shown in FIG. 9.

As an example, when the light emitted from the light emitting diode 200 has a maximum luminance at a viewing angle of 60°, the light emitting diode display device according to the reference example may have a maximum luminance at a viewing angle of 60° and a low luminance at a front surface (0°), whereby it may have an inefficient luminance distribution.

On the other hand, the light emitting diode display device according to the Aspect 1 may have the same or substantially same structure as the light emitting diode shown in FIG. 8. The light emitting diode display device according to the Aspect 1 may further include the low refractive pattern 250 and the high refractive planarization layer 260 provided on the light emitting diode 200 in comparison with the light emitting diode display device according to the reference example.

The light emitting diode display device according to the Aspect 1 may change the path of light generated by the light emitting diode 200 to the direction of viewing angle 0° by means of the low refractive pattern 250. Particularly, in the light emitting diode display device according to the Aspect 1, the light in the vicinity of viewing angle 60° having a maximum luminance is totally reflected on the inclined surface S3 of the low refractive pattern 250 so that it is possible to change the path of light to the direction of viewing angle θ.

Accordingly, as shown in FIG. 10, in case of the light emitting diode display device according to the Aspect 1, the luminance of light in the vicinity of viewing angle 60° is reduced, whereas the luminance of light near the viewing angle 0° may be increased, as compared to the light emitting diode display device according to the reference example. As a result, referring to FIG. 10, on assumption that the luminance at the front surface, for example, viewing angle 0° in the light emitting diode display device according to the reference example is 100%, the luminance at the front surface in the light emitting diode display device according to the Aspect 1 is 120%, whereby the luminance at the front surface in the light emitting diode display device according to the Aspect 1 is increased by 20% as compared with that of the light emitting diode display device according to the reference example.

Also, the light emitting diode display device according to the Aspect 2 may have the same or substantially same structure as the light emitting diode shown in FIG. 3. The light emitting diode display device according to the Aspect 2 may further include the low refractive pattern 250, the high refractive planarization layer 260, the high refractive lens 270, and the low refractive planarization layer 280 provided on the light emitting diode 200 as compared with the light emitting diode display device according to the reference example.

The light emitting diode display device according to the Aspect 2 may change the path of light generated by the light emitting diode 200 to the direction of viewing angle 0° by the low refractive pattern 250 and may collect the light by the high refractive lens 270. Particularly, in the light emitting diode display device according to the Aspect 2, the light in the vicinity of viewing angle 60° having a maximum luminance is totally reflected on the inclined surface S3 of the low refractive pattern 250 so that it is possible to change the path of light to the direction of viewing angle θ.

Also, in the light emitting diode display device according to the Aspect 2, the light whose path is changed by the low refractive pattern 250 may be collected by the high refractive lens 270 and may be emitted to the outside.

Accordingly, as shown in FIG. 11, in case of the light emitting diode display device according to the Aspect 2, the luminance of light in the vicinity of viewing angle 60° is reduced, whereas the luminance of light near the viewing angle 0° may be increased, as compared to the light emitting diode display device according to the reference example. As a result, referring to FIG. 11, on assumption that the luminance at the front surface, for example, viewing angle 0° in the light emitting diode display device according to the reference example is 100%, the luminance at the front surface in the light emitting diode display device according to the Aspect 2 is 150%, whereby the luminance at the front surface in the light emitting diode display device according to the Aspect 2 is increased by 50% as compared with that of the light emitting diode display device according to the reference example.

Also, in case of the light emitting diode display device according to the Aspect 2, the path of light is changed by the low refractive pattern 250, and is then collected by the high refractive lens 270, whereby the luminance at the front surface in the light emitting diode display device according to the Aspect 2 may be further increased as compared to that of the light emitting diode display device according to the Aspect 1.

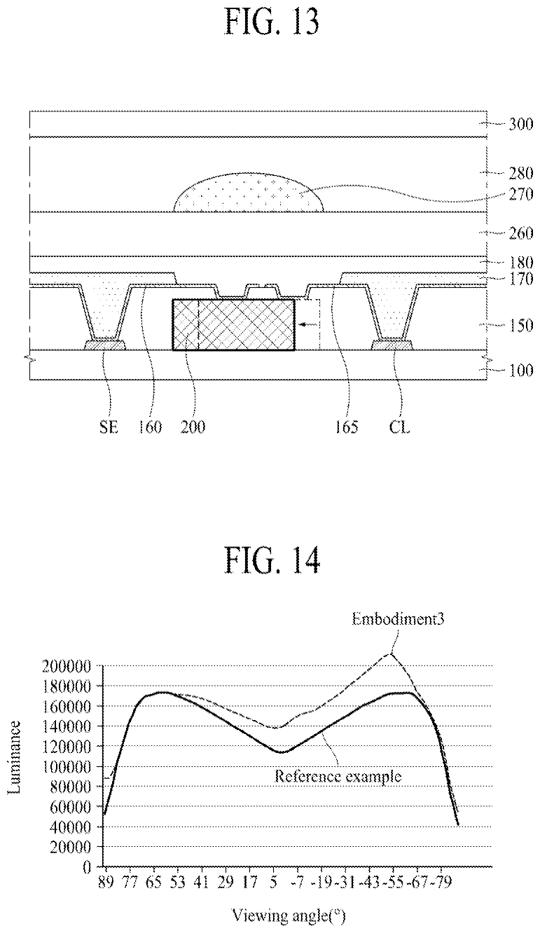

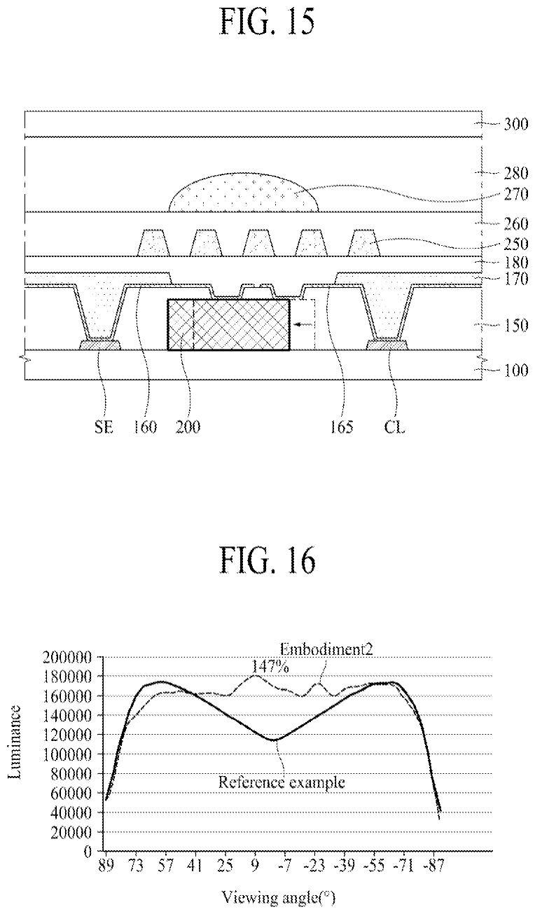

FIG. 12 shows a luminance distribution for each viewing angle of a light emitting diode display device according to Aspect 3 provided with a high refractive lens, FIG. 13 illustrates an example in which a transfer tolerance occurs in the light emitting diode display device according to the Aspect 3, and FIG. 14 illustrates a luminance distribution for each viewing angle of the light emitting diode display device according to the Aspect 3 in which a transfer tolerance occurs. FIG. 15 illustrates an example in which a transfer tolerance occurs in the light emitting diode display device according to the Aspect 2, and FIG. 16 illustrates a luminance distribution for each viewing angle of the light emitting diode display device according to the Aspect 2 in which a transfer tolerance occurs.

The light emitting diode display device according to the Aspect 3 may have the structure in which the low refractive pattern 250 and the high refractive planarization layer 260 are omitted from the light emitting diode display device shown in FIG. 3. The light emitting diode display device according to the Aspect 3 may further include the high refractive lens 270 and the low refractive planarization layer 280 provided on the light emitting diode 200 in comparison with the light emitting diode display device according to the reference example.

In the light emitting diode display device according to the Aspect 3, the light generated by the light emitting diode 200 may be collected by the high refractive lens 270. Accordingly, as shown in FIG. 12, in case of the light emitting diode display device according to the Aspect 3, there may be an area where the light is collected at a viewing angle which is smaller than viewing angle 60°, as compared to the light emitting diode display device according to the reference example.

As a result, in case of the light emitting diode display device according to the Aspect 3, the light is increased at a viewing angle smaller than viewing angle 60°, as compared to the light emitting diode display device according to the reference example, thereby improving the front luminance and overcoming, addressing or reducing inefficient luminance distribution.

In the light emitting diode display device according to the Aspect 3, when the light emitting diode 200 is transferred to the first substrate 100, as shown in FIG. 13, the light emitting diode 200 may not be disposed at an accurate position and a transfer tolerance may occur. In the light emitting diode display device according to the Aspect 3 in which the transfer tolerance occurs, according as the light emitting diode 200 is biased to one side, the luminance distribution for each viewing angle is not symmetrically provided in the left and right sides and may be biased in one direction as shown in FIG. 14.

On the other hand, as shown in FIG. 15, in case of the light emitting diode display device according to the Aspect 2 in which the transfer tolerance occurs, even though the light emitting diode 200 is biased to one side, the luminance distribution for each viewing angle may not be biased in one direction as shown in FIG. 16. As a result, the light emitting diode display device according to the Aspect 2 has the low refractive pattern 250 on the light emitting diode 200 so that it is possible to improve the front luminance, to overcome, address or reduce the inefficient luminance distribution for each viewing angle of the light emitting diode 200, and to prevent or reduce the luminance distribution for each viewing angle from being biased to one direction even in case of the occurrence of the transfer tolerance.

According to the present disclosure, the low refractive pattern is provided on the light emitting diode, thereby increasing the front luminance and improving the luminance distribution for each inefficient viewing angle of the light emitting diode.

Also, even though a transfer tolerance occurs, it is possible to prevent or reduce the luminance distribution for each viewing angle from being biased to one side.

Also, the low refractive pattern has the taper angle which totally reflects the light of viewing angle having the maximum luminance so that it is possible to change the path in the amount of light to the front direction. Thus, it is possible to improve the luminance in the viewing angle 0°, for example, the front surface.

In addition, the low refractive pattern is covered with the high refractive planarization layer having the higher refractive index than that of the low refractive pattern, thereby increasing the amount of light totally reflected on the inclined surface of the low refractive pattern and increasing the light collection effect of the high refractive lens by securing the optical distance between the light emitting diode and the high refractive lens.

In addition, since the high refractive lens is provided on the high refractive planarization layer, the high refractive lens condenses the light whose path is changed by the low refractive pattern, thereby further increasing the front luminance of the light emitting diode display device.

It will be apparent to those skilled in the art that various substitutions, modifications, and variations are possible within the scope of the present disclosure without departing from the technical idea and scope of the present disclosure. Therefore, the scope of the present disclosure may be represented by the following claims, and all changes or modifications derived from the meaning, range and equivalent concept of the claims should be interpreted as being included in the scope of the present disclosure.

What is claimed is:

1. A light emitting diode display device comprising:
a light emitting diode over a substrate;
a plurality of patterns provided over the light emitting diode and having a first refractive index, each of the plurality of patterns including an inclined surface;
a first planarization layer provided over the plurality of patterns and having a second refractive index different from the first refractive index.

2. The light emitting diode display device according to claim 1, further comprising a lens provided over the first planarization layer.

3. The light emitting diode display device according to claim 1, wherein the first planarization layer is disposed between adjacent two patterns among the plurality of patterns.

4. The light emitting diode display device according to claim 1, wherein the second refractive index is greater than the first refractive index.

5. The light emitting diode display device according to claim 2, wherein the lens is disposed in the light emitting diode in a one-to-one correspondence.

6. The light emitting diode display device according to claim 3, wherein the lens overlaps with the plurality of patterns.

7. The light emitting diode display device according to claim 1, wherein the light emitting diode has a maximum luminance at a first viewing angle, and
wherein the plurality of patterns totally reflect light of the first viewing angle emitted from light emitting diode on the inclined surface.

8. The light emitting diode display device according to claim 1, wherein the inclined surface of the plurality of patterns has a tapered angle of 5° to 40°.

9. The light emitting diode display device according to claim 4, wherein a diameter of an upper surface of the plurality of patterns is smaller than a diameter of a lower surface of the plurality of patterns.

10. The light emitting diode display device according to claim 1, wherein each of the plurality of patterns has a groove on the upper surface thereof.

11. The light emitting diode display device according to claim 4, wherein each of the plurality of patterns has one of a conical shape, a polygonal pyramid shape, a truncated cone shape, and a polygonal pyramid shape.

12. The light emitting diode display device according to claim 2, wherein the lens has a third refractive index greater than the first refractive index.

13. The light emitting diode display device according to claim 2, further comprising a second planarization layer provided over the lens and configured to have a fourth refractive index smaller than the third refractive index.

14. The light emitting diode display device according to claim 2, further comprising a bank including an opening area corresponding to a light emitting area in which light emitted from the light emitting diode is emitted outside the light emitting diode display device,
wherein the plurality of patterns are arranged in the opening area of the bank.

15. The light emitting diode display device according to claim 14, wherein the bank includes a light absorbing material.

16. The light emitting diode display device according to claim 14, wherein the light emitting area includes an effective area having a circular shape with a first diameter with respect to the light emitting diode, and
wherein the plurality of patterns are arranged in the effective area.

17. The light emitting diode display device according to claim 16, wherein the number of the plurality of patterns arranged in the effective area is equal to or larger than three.

18. The light emitting diode display device according to claim 16, wherein the first diameter of the effective area is twice a length of a short axis of the light emitting diode.

19. The light emitting diode display device according to claim 16, wherein the lens has a second diameter greater than the first diameter.

20. The light emitting diode display device according to claim 1, wherein the light emitting diode includes:
a first semiconductor layer;
an active layer over one side of the first semiconductor layer;
a second semiconductor layer over the active layer;
a first electrode over the second semiconductor layer; and
a second electrode over the other side of the first semiconductor layer.

21. The light emitting diode display device according to claim 20, further comprising:
a driving thin film transistor;
a first connection electrode electrically connecting the driving thin film transistor and the first electrode of the light emitting diode; and
a second connection electrode electrically connected to the second electrode of the light emitting diode,
wherein the pattern is provided over the first connection electrode and the second connection electrode.
